(19) United States
(12) Patent Application Publication
(10) Pub. No.: US 2026/0032893 A1
(43) Pub. Date: Jan. 29, 2026

(54) THREE-DIMENTIONAL SEMICONDUTOR DEVICE AND METHOD OF FABRICATING THE SAME

(71) Applicant: Samsung Electronics Co., Ltd., Suwon-si (KR)

(72) Inventors: Woojong Shin, Suwon-si (KR); Haneol Kim, Suwon-si (KR); Gwang-Hyun Baek, Suwon-si (KR); Jinkwan Lee, Suwon-si (KR); Je-Woo Han, Suwon-si (KR)

(21) Appl. No.: 19/042,914

(22) Filed: Jan. 31, 2025

(30) Foreign Application Priority Data
Jul. 23, 2024 (KR) 10-2024-0097422

(51) Int. Cl. H10B 12/00

(52) U.S. Cl. CPC H10B 12/488; H10B 12/02

(57) ABSTRACT

A three-dimensional semiconductor device includes a substrate including a cell region and an extension region, a stack on the extension region, a first word line contact that extends into at least one gate connection line of the stack and is connected to a first gate connection line of the at least one gate connection line, a first spacer between the first word line contact and the stack, and a second spacer between the first spacer and the first word line contact. A first portion of the second spacer is spaced apart from the at least one first gate connection line by the first spacer, a second portion of the second spacer is in contact with the at least one first gate connection line, and the first portion of the second spacer is on the second portion of the second spacer.

### CROSS-REFERENCE TO RELATED APPLICATIONS

This U.S. non-provisional patent application claims priority under 35 U.S.C. § 119 to Korean Patent Application No. 10-2024-0097422, filed on Jul. 23, 2024, in the Korean Intellectual Property Office, the entire contents of which are hereby incorporated by reference.

### TECHNICAL FIELD

The present disclosure relates to a three-dimensional semiconductor device and a method of fabricating the same, and in particular, to a three-dimensional semiconductor device with improved reliability and a higher integration density.

### BACKGROUND

Due to their small-sized, multifunctional, and/or low-cost characteristics, semiconductor devices are being esteemed as desired elements in the electronics industry. The semiconductor devices may be classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices are also desired to have high operating speeds and/or low operating voltages, and in order to satisfy these characteristics, it is desirable to increase an integration density of the semiconductor device. However, as the integration density of the semiconductor device increases, the semiconductor device may suffer from deteriorated electrical characteristics and low production yield. Accordingly, many studies are being conducted to improve the electrical characteristics and production yield of the semiconductor device.

### SUMMARY

Some embodiments of the present disclosure provides a three-dimensional semiconductor device with improved electrical characteristics and high yield and a method of fabricating the same.

According to some embodiments of the present disclosure, a three-dimensional semiconductor device may include a substrate including a cell region and an extension region, a stack on the extension region, the stack including a plurality of gate connection lines and a plurality of interlayer insulating layers alternately stacked on the substrate, a first word line contact that extends into at least one gate connection line of the plurality of gate connection lines and is connected to a first gate connection line of the at least one gate connection line, a first spacer between the first word line contact and the stack, and a second spacer between the first spacer and the first word line contact. A first portion of the second spacer is spaced apart from the at least one first gate connection line by the first spacer, a second portion of the second spacer is in contact with the at least one first gate connection line, and the first portion of the second spacer is on the second portion of the second spacer.

According to some embodiments of the present disclosure, a three-dimensional semiconductor device may include a substrate including a cell region and an extension region, a stack on the extension region, the stack including a plurality of gate connection lines and a plurality of interlayer insulating layers that are alternately stacked on the substrate, a word line contact that extends into at least one gate connection line of the plurality of gate connection lines and is connected to a first gate connection line of the at least one gate connection line, and a spacer between the word line contact and the stack. The spacer includes protruding portions that extend in a first direction that is parallel to a top surface of the substrate, and the protruding portions are spaced apart from each other in a second that is direction perpendicular to the top surface of the substrate.

According to some embodiments of the present disclosure, a three-dimensional semiconductor device may include a substrate including a cell region and an extension region, a first cell array structure and a second cell array structure that are on the cell region and are spaced apart from each other in a first direction that is parallel to a top surface of the substrate, a stack that is on the extension region and between the first cell array structure and the second cell array structure, the stack including a plurality of gate connection lines and a plurality of interlayer insulating layers that are alternately stacked on the substrate, a word line contact that extends into at least one gate connection line of the plurality of gate connection lines and is connected to a first gate connection line of the plurality of gate connection lines, a first spacer between the word line contact and the stack, and a second spacer between the first spacer and the word line contact. Each of the first cell array structure and the second cell array structure includes: a plurality of semiconductor patterns that are spaced apart from each other in a second direction that is perpendicular to the top surface of the substrate, word lines that at least partially surround the semiconductor patterns and extend in the first direction, a bit line that is connected to a first end portion of each of the plurality of semiconductor patterns and extends in the second direction, and a data storage pattern that is connected to a second end portion of each of the plurality of semiconductor patterns and extends in the second direction. A first portion of the second spacer is spaced apart from the at least one gate connection line by the first spacer, a second portion of the second spacer is in contact with the at least one gate connection line, and the first portion of the second spacer is on the second portion of the second spacer.

According to some embodiments of the present disclosure, a method of fabricating a three-dimensional semiconductor device may include providing a substrate including a cell region and an extension region, forming a mold structure including sacrificial layers and interlayer insulating layers that are alternately stacked on the extension region, performing a first patterning process to form a contact hole that extends into a portion of the mold structure, forming a first spacer on a bottom surface of the contact hole, removing a portion of the first spacer on the bottom surface of the contact hole to expose the mold structure, and performing a second patterning process to remove the a first portion of the mold structure that is exposed by the contact hole, where during the second patterning process, the first spacer remains on an inner side surface of the mold structure that defines an inner side surface of the contact hole.

### BRIEF DESCRIPTION OF THE DRAWINGS

FIG. 1 is a circuit diagram schematically illustrating a three-dimensional semiconductor device according to some embodiments of the present disclosure.

FIGS. 2A, 2B, and 2C are perspective views schematically illustrating a three-dimensional semiconductor device according to some embodiments of the present disclosure.

FIG. 3 is a plan view illustrating a three-dimensional semiconductor device according to some embodiments of the present disclosure.

FIG. 4 is an enlarged plan view corresponding to a portion ‘P1’ of FIG. 3.

FIG. 5 is a sectional view corresponding to a line A-A′ of FIG. 3.

FIG. 6 is a sectional view corresponding to a line B-B′ of FIG. 3.

FIGS. 7 to 12 are sectional views corresponding to the line A-A′ of FIG. 3.

FIGS. 13 to 17 are diagrams illustrating a method of fabricating a three-dimensional semiconductor device, according to some embodiments of the present disclosure.

FIG. 18 is a plan view illustrating a three-dimensional semiconductor device according to some embodiments of the present disclosure.

FIG. 19 is a sectional view corresponding to a line A-A′ of FIG. 18.

### DETAILED DESCRIPTION

Example embodiments of the present disclosure will now be described more fully with reference to the accompanying drawings, in which example embodiments are shown.

To clarify the present disclosure, the same elements or equivalents are referred to by the same reference numerals throughout the specification. Further, since sizes and thicknesses of constituent members shown in the accompanying drawings are arbitrarily given for better understanding and case of description, the present disclosure is not limited to the illustrated sizes and thicknesses. In the drawings, the thickness of layers, films, panels, regions, etc., are exaggerated for clarity. In the drawings, for better understanding and case of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for case of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction.

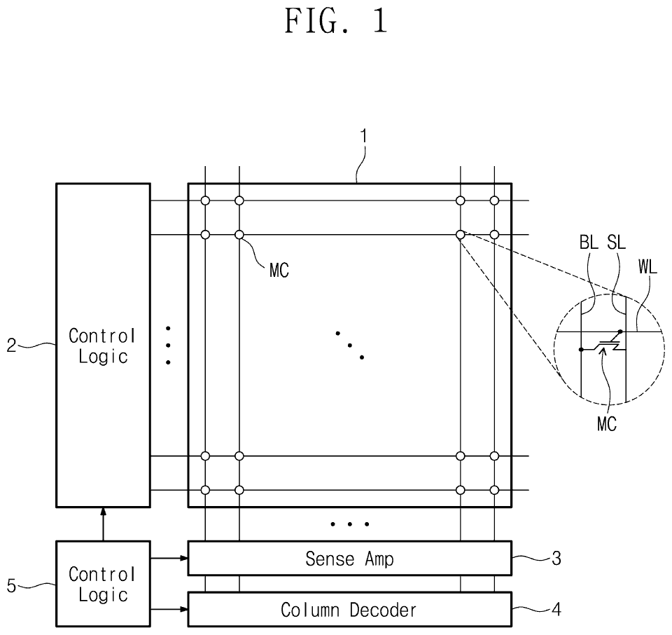

FIG. 1 is a circuit diagram schematically illustrating a three-dimensional semiconductor device according to some embodiments of the present disclosure.

Referring to FIG. 1, a three-dimensional semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each of the memory cells MC may be connected to one of the word lines WL, one of the bit lines BL, and one of the source lines SL. In some embodiments, each of the memory cells MC may be composed of one transistor including a memory layer or a data storing layer.

The row decoder 2 may be configured to decode address information, which is input from the outside, and to select one of the word lines WL of the memory cell array 1 based on the decoded address information. The address information decoded by the row decoder 2 may be provided to a row driver (not shown), and in this case, the row driver may provide respective voltages to the selected one of the word lines WL and the unselected ones of the word lines WL in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may establish a data transmission path between the sense amplifier 3 and an external device (e.g., a memory controller). The column decoder 4 may be configured to decode address information, which is input from the outside, and to select one of the bit lines BL based on the decoded address information.

The control logic 5 may be configured to generate control signals, which are used to control data-writing or data-reading operations on the memory cell array 1.

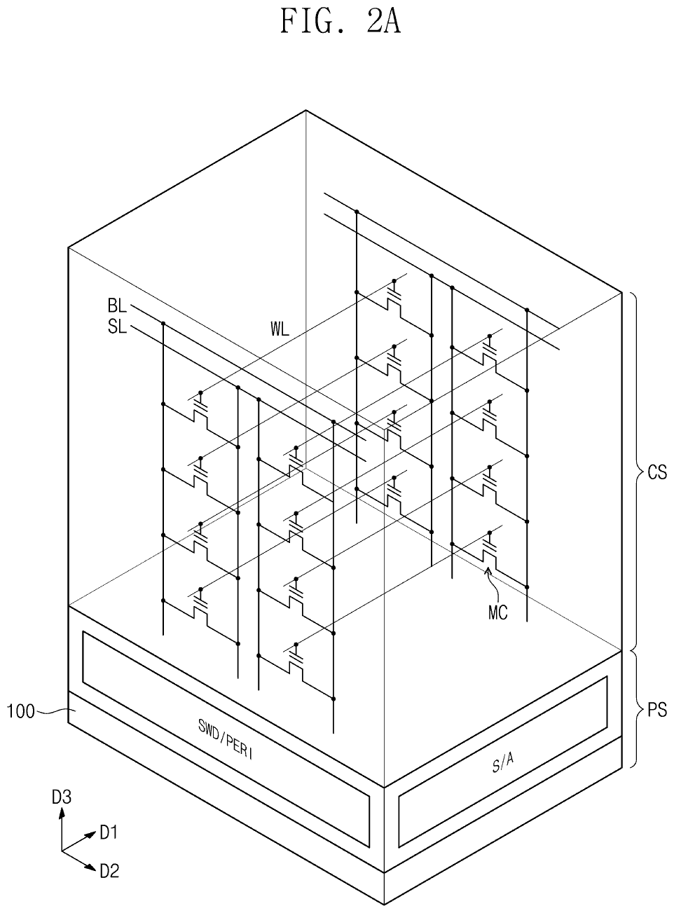

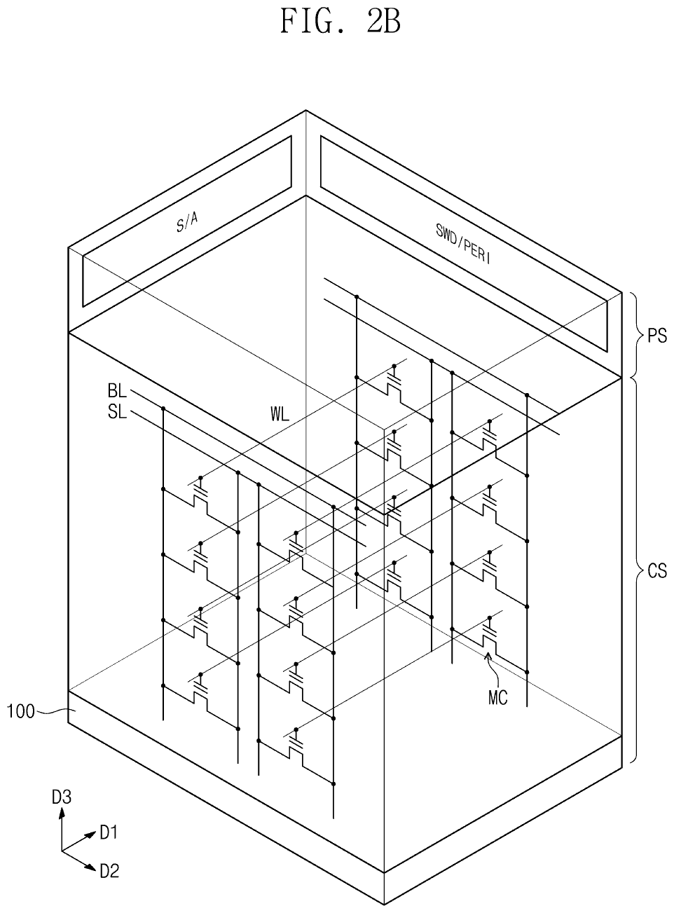

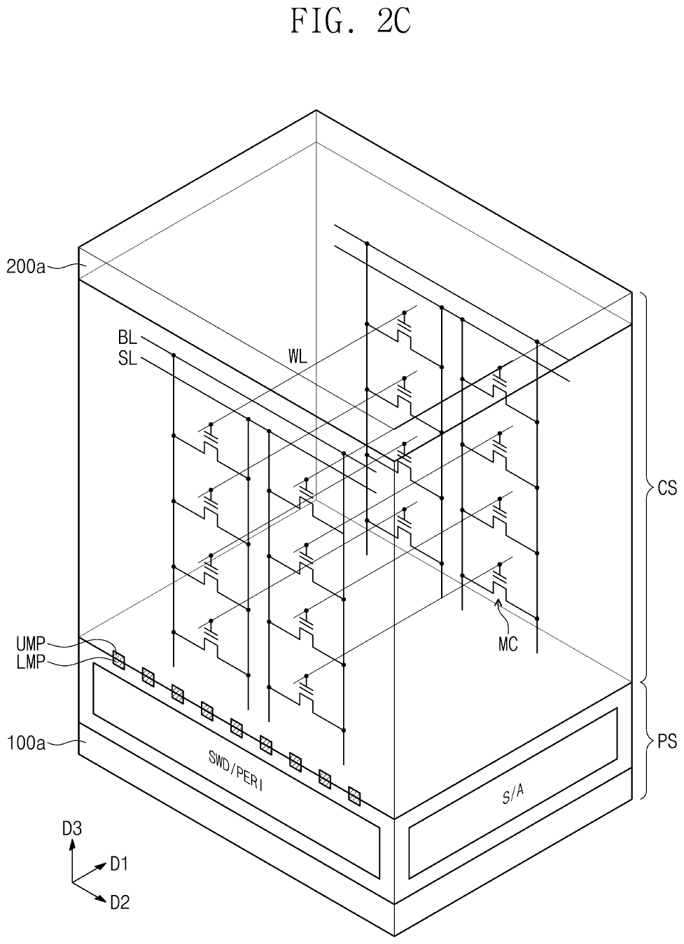

FIGS. 2A, 2B, and 2C are perspective views schematically illustrating a three-dimensional semiconductor device according to some embodiments of the present disclosure.

Referring to FIG. 2A, a three-dimensional semiconductor device may include a substrate 100, a peripheral circuit structure PS on the substrate 100, and a cell array structure CS on the peripheral circuit structure PS.

The peripheral circuit structure PS may include core and peripheral circuits, which are formed on the substrate 100. The core and peripheral circuits may include the row and column decoders 2 and 4, the sense amplifier 3, and the control logic 5 described with reference to FIG. 1.

The substrate 100 may be a plate-shaped structure that extends parallel to a plane defined by a first direction D1 and a second direction D2. The first and second directions D1 and D2 may be parallel to a bottom surface of the substrate 100 and may not be parallel to each other. In some embodiments, the first and second directions D1 and D2 may be horizontal directions that are orthogonal to each other. The peripheral circuit structure PS and the cell array structure CS may be sequentially stacked on the substrate 100 in a third direction D3 perpendicular to the bottom surface of the substrate 100.

The cell array structure CS may include the bit lines BL, the source lines SL, the word lines WL, and the memory cells MC therebetween. Each of the memory cells MC may be connected to one of the word lines WL, one of the bit lines BL, and one of the source lines SL.

Referring to FIG. 2B, the semiconductor device may include the cell array structure CS on the substrate 100 and the peripheral circuit structure PS on the cell array structure CS. The cell array structure CS may be disposed between the substrate 100 and the peripheral circuit structure PS. The peripheral circuit structure PS may include the core and peripheral circuits.

Referring to FIG. 2C, the semiconductor device may have a chip-to-chip (C2C) structure. The peripheral circuit structure PS may include a first substrate 100a. Lower metal pads LMP may be provided in the uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided in the lowermost portion of the cell array structure CS. The upper metal pads UMP may be electrically connected to the bit lines BL, the source lines SL, and the word lines WL. The upper metal pads UMP may be electrically connected to the memory cells MC.

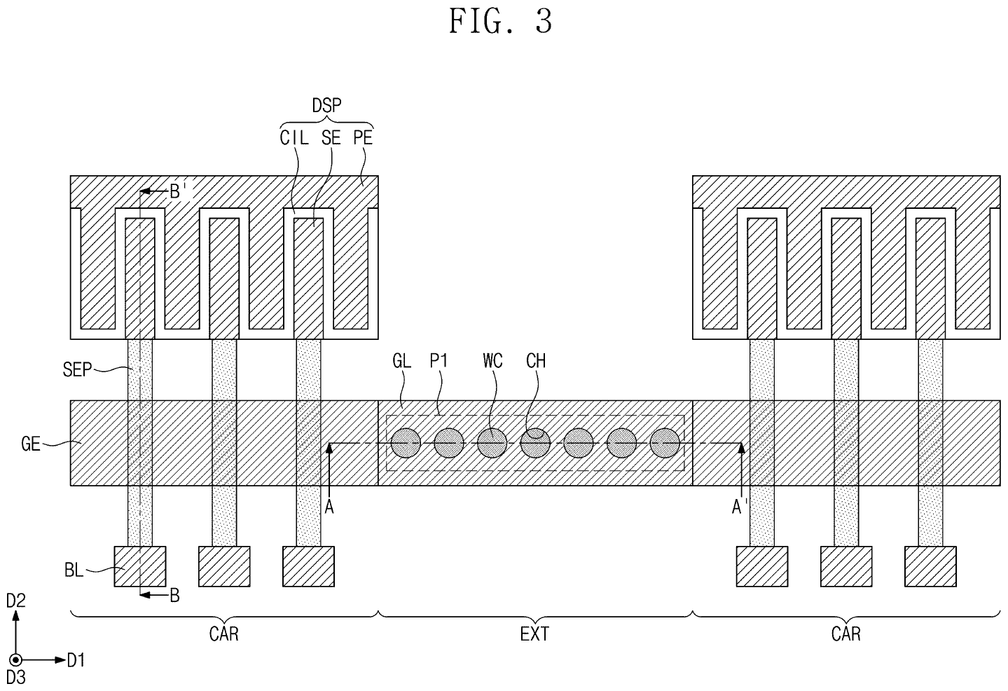

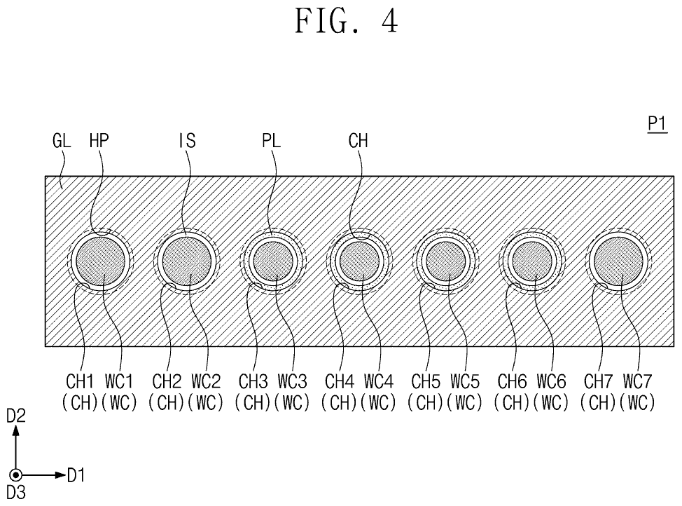

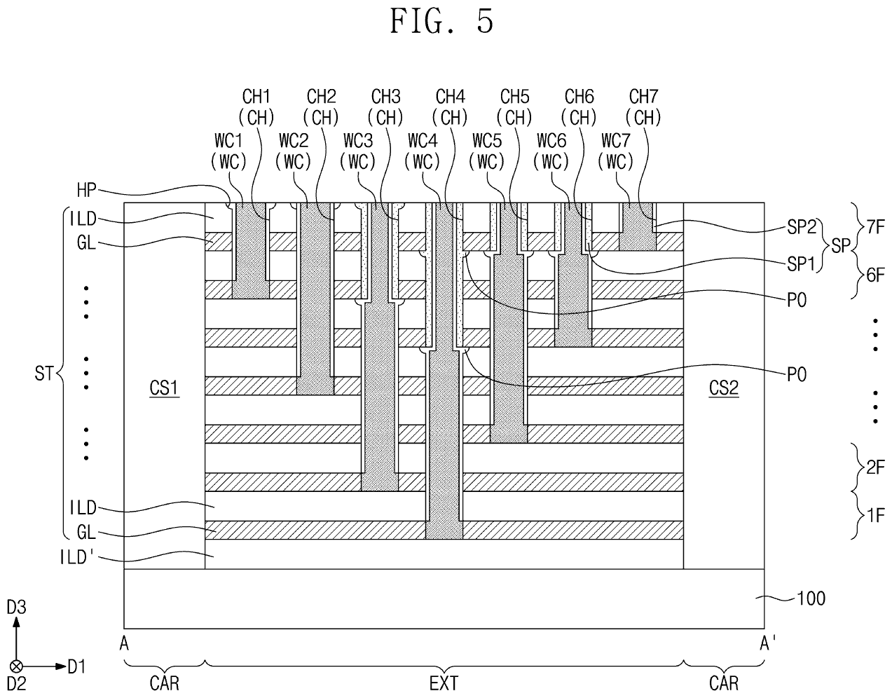

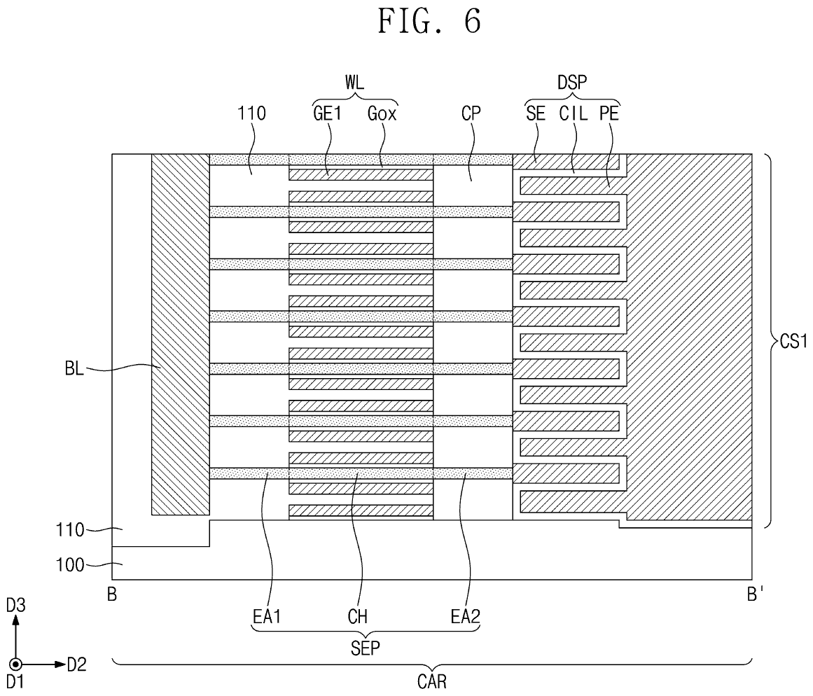

FIG. 3 is a plan view illustrating a three-dimensional semiconductor device according to some embodiments of the present disclosure. FIG. 4 is an enlarged plan view corresponding to a portion ‘P1’ of FIG. 3. FIG. 5 is a sectional view corresponding to a line A-A′ of FIG. 3. FIG. 6 is a sectional view corresponding to a line B-B′ of FIG. 3.

Referring to FIGS. 3 to 6, the three-dimensional semiconductor device may include the substrate 100. In some embodiments, the substrate 100 may be a semiconductor substrate, an insulating substrate, a silicon-on-insulator (SOI) substrate, or a germanium-on-insulator (GOI) substrate. The semiconductor substrate may be, for example, a silicon substrate, a germanium substrate, or a silicon-germanium substrate. The substrate 100 may be a plate-shaped structure that extends parallel to a plane defined by the first and second directions D1 and D2. The first and second directions D1 and D2 may be parallel to a top surface of the substrate 100 and may not be parallel to each other. In some embodiments, the substrate 100 may include the peripheral circuit structure PS described with reference to FIGS. 2A and 2C.

The substrate 100 may include cell regions CAR and an extension region EXT. The cell regions CAR may be adjacent to each other in the first direction D1, with the extension region EXT interposed therebetween. The cell array structure CS described with reference to FIGS. 2A to 2C may be provided in the cell region CAR.

A first cell array structure CS1 and a second cell array structure CS2 may be provided on the substrate 100. Each of the first and second cell array structures CS1 and CS2 may be provided on the cell region CAR. The first and second cell array structures CS1 and CS2 may be spaced apart from each other in the first direction D1. Each of the first and second cell array structures CS1 and CS2 may correspond to the cell array structure CS described with reference to FIGS. 2A to 2C. Elements, which are included in each of the first and second cell array structures CS1 and CS2, will be described below.

A stack ST may be provided between the first and second cell array structures CS1 and CS2. The stack ST may be provided on the extension region EXT. The height of the stack ST may be substantially constant in the third direction D3 regardless of the position in the first direction D1. In other words, when viewed in a sectional view, the stack ST may not have a staircase structure. Accordingly, a width of the stack ST in the first direction D1 may be small, compared with the stack ST having the staircase structure. As a result, the extension region EXT may be formed to have a small width in the first direction D1. Thus, the integration density of the three-dimensional semiconductor device may be increased.

When measured in the third direction D3, a width of the stack ST in the first direction D1 may be substantially constant and may be decreased. Two cell array structures and one stack are illustrated in the drawings, but the present disclosure is not limited to this example. The numbers of the cell array structures and the stacks may be variously changed.

The stack ST may include gate connection lines GL and interlayer insulating layers ILD, which are alternately stacked on the substrate 100 in the third direction D3. Each of the gate connection lines GL and the interlayer insulating layers ILD may extend in the first direction D1. The gate connection line GL may be connected to a gate electrode GE of the word line WL in each of the first and second cell array structures CS1 and CS2. The gate connection line GL may be connected to the gate electrodes GE of the word lines WL, which are located at substantially the same vertical level (e.g., a height of the gate connection lines GL and a height of the gate electrodes GE in the third direction D3 are substantially the same). The lowermost interlayer insulating layer ILD' may be additionally provided between the stack ST and the substrate 100.

In some embodiments, the gate connection line GL may be formed of or include at least one of doped semiconductor materials (e.g., doped silicon and doped germanium), metallic materials (e.g., Ti, Mo, W, Cu, Al, Ta, Ru, Ir, and Co), metal silicide materials (e.g., silicide materials of Ti, Mo, W, Cu, Al, Ta, Ru, Ir, and Co), or metal nitride materials (e.g., nitride materials of Ti, Mo, W, Cu, Al, Ta, Ru, Ir, and Co). The interlayer insulating layer ILD may be formed of or include at least one of insulating materials (e.g., SiO₂ and SiN).

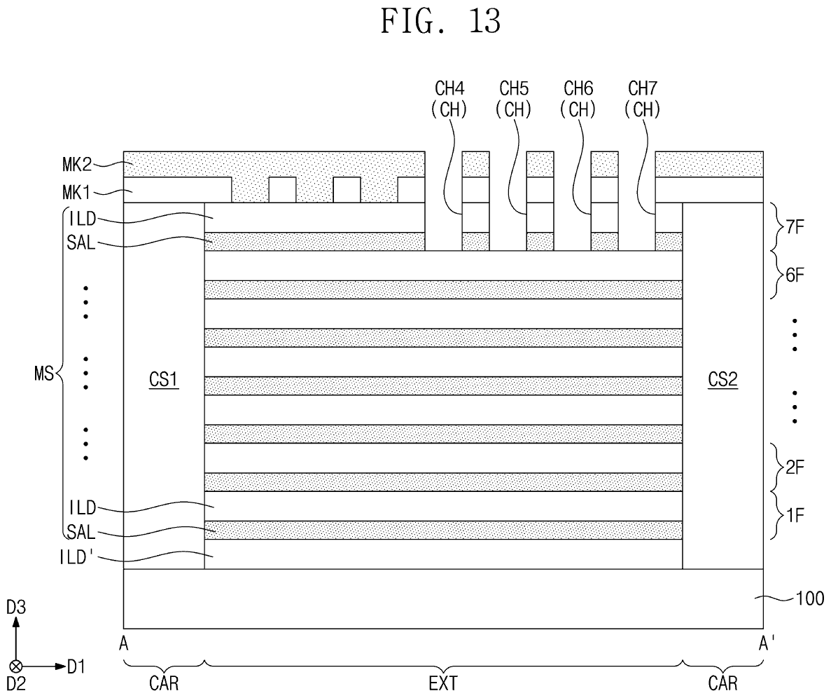

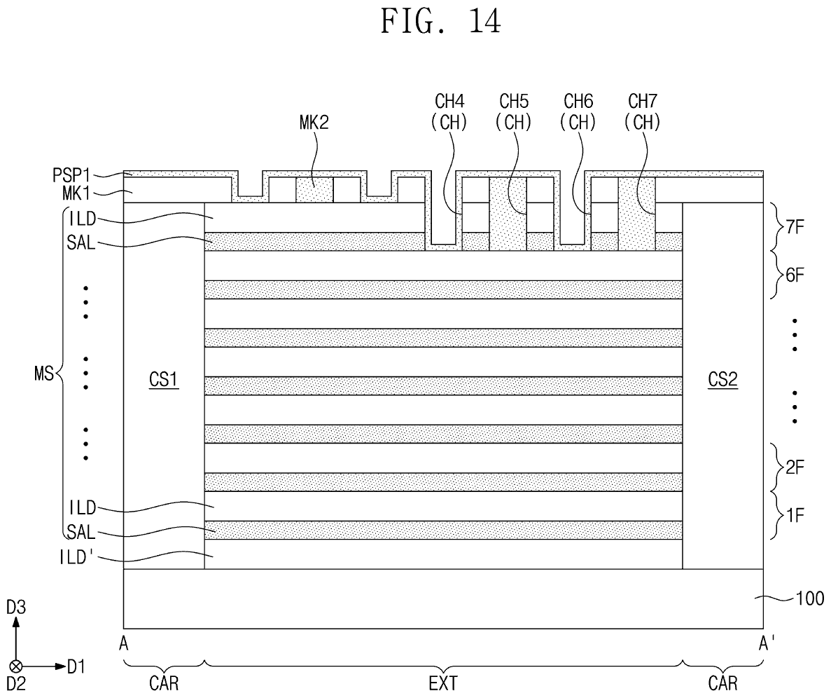

In some embodiments, the stack ST may include a 7 unit-layer stacked structure. In the present specification, an expression of “n unit-layer stacked structure” may be used to represent a structure, in which n gate connection lines GL and n interlayer insulating layers ILD are alternately stacked. That is, the 7 unit-layer stacked structure may mean a structure in which seven gate connection lines GL and seven interlayer insulating layers ILD are alternately stacked. The stack ST is illustrated as the 7 unit-layer stacked structure, but the inventive concept is not limited to this example. The number of the unit-layers in the stack ST may be changed, as described in more detail with reference to FIGS. 13 and 14.

A contact hole CH may be provided to penetrate or extend into a portion of the stack ST. In some embodiments, a plurality of contact holes CH may be provided. Although first to seventh contact holes CH1, CH2, CH3, CH4, CH5, CH6, and CH7 are illustrated, the present disclosure is not limited to this example. In some embodiments, the number of the contact holes CH may be variously changed depending on the number of the unit-layers in the stack ST. Each of the first to seventh contact holes CH1, CH2, CH3, CH4, CH5, CH6, and CH7 may be provided to penetrate or extend into at least one of the gate connection lines GL.

A word line contact WC may be provided to penetrate or extend into at least one of the gate connection lines GL and may be connected to the gate connection line GL. The word line contact WC may be connected to the gate electrode GE of the word line WL through the gate connection line GL. The word line contact WC may be provided to at least partially fill the contact hole CH. In some embodiments, the word line contact WC may be formed of or include at least one of doped semiconductor materials (e.g., doped silicon and doped germanium), metallic materials (e.g., Ti, Mo, W, Cu, Al, Ta, Ru, Ir, and Co), metal silicide materials (e.g., silicide materials of Ti, Mo, W, Cu, Al, Ta, Ru, Ir, and Co), or metal nitride materials (e.g., nitride materials of Ti, Mo, W, Cu, Al, Ta, Ru, Ir, and Co).

In some embodiments, a plurality of word line contacts WC may be provided. Each of the word line contacts WC may be connected to a corresponding one of the gate connection lines GL. Each of the word line contacts WC may be connected to a corresponding one of the gate connection lines GL. In other words, a plurality of word line contacts WC may not share one gate connection line GL.

Although first to seventh word line contacts WC1, WC2, WC3, WC4, WC5, WC6, and WC7 are illustrated, the present disclosure is not limited to this example. The number of the word line contacts WC may be variously changed depending on the number of the unit-layers in the stack ST. In addition, although the first to seventh word line contacts WC1, WC2, WC3, WC4, WC5, WC6, and WC7 are illustrated to be sequentially arranged in the first direction D1, the present disclosure is not limited to this example. The arrangement order thereof may be variously changed. Each of the first to seventh word line contacts WC1, WC2, WC3, WC4, WC5, WC6, and WC7 may be provided to penetrate or extend into at least one of the gate connection lines GL.

In detail, the first word line contact WC1 may be provided to penetrate or extend into 2 unit-layers. For example, the first word line contact WC1 may be provided to penetrate or extend into the sixth and seventh unit-layers 6F and 7F of the stack ST or the gate connection line GL of each of them.

The second word line contact WC2 may be provided to penetrate or extend into 4 unit-layers. For example, the second word line contact WC2 may be provided to penetrate or extend into the fourth to seventh unit-layers 4F to 7F of the stack ST or the gate connection line GL of each of them.

The third word line contact WC3 may be provided to penetrate or extend into 6 unit-layers. For example, the third word line contact WC3 may be provided to penetrate or extend into the second to seventh unit-layers 2F to 7F of the stack ST or the gate connection line GL of each of them.

The fourth word line contact WC4 may be provided to penetrate or extend into 7 unit-layers. For example, the fourth word line contact WC4 may be provided to penetrate or extend into the first to seventh unit-layers 1F to 7F of the stack ST or the gate connection line GL of each of them.

The fifth word line contact WC5 may be provided to penetrate or extend into 5 unit-layers. For example, the fifth word line contact WC5 may be provided to penetrate or extend into the third to seventh unit-layers 3F to 7F of the stack ST or the gate connection line GL of each of them.

The sixth word line contact WC6 may be provided to penetrate or extend into 3 unit-layers. For example, the sixth word line contact WC6 may be provided to penetrate or extend into the fifth to seventh unit-layers 5F to 7F of the stack ST or the gate connection line GL of each of them.

The seventh word line contact WC7 may be provided to penetrate or extend into a 1 unit-layer. For example, the seventh word line contact WC7 may be provided to penetrate or extend into the seventh unit-layer 7F of the stack ST or the gate connection line GL of each thereof.

A spacer SP may be interposed between the word line contact WC and the stack ST. The spacer SP may include a first spacer SP1 between the word line contact WC and the stack ST and a second spacer SP2 between the first spacer SP1 and the word line contact WC. In some embodiments, the first spacer SP1 may include at least one of SiN or SiO₂. In some embodiments, the second spacer SP2 may include SiO₂.

The second spacer SP2 may cover or at least partially overlap a side surface of the word line contact WC. In detail, the second spacer SP2 may cover or overlap a portion of the side surface of the word line contact WC and not cover or overlap another portion of the side surface of the word line contact WC in contact with the gate connection line GL. Accordingly, the word line contact WC may be connected to one of the gate connection lines GL but may be physically separated and electrically disconnected from the others of the gate connection lines GL by the second spacer SP2.

In the case where the first spacer SP1 is provided on the word line contact WC, the first spacer SP1 may cover or overlap a portion of the side surface of the word line contact WC. A bottom surface of the first spacer SP1 may be located at a vertical level higher than a bottom surface of the second spacer SP2 (e.g., a distance between the bottom surface of the first spacer SP1 and a top surface of the substrate 100 in the third direction D3 is greater than a distance between a bottom surface of the second spacer SP2 and the top surface of the substrate 100 in the third direction D3). Accordingly, the second spacer SP2 may include a first portion, which is provided on the word line contact WC and is spaced apart from at least one of the gate connection lines GL by the first spacer SP1. In some embodiments, the second spacer SP2 may include a second portion that is in contact with at least one of the gate connection lines GL. The second portion of the second spacer SP2 may be placed below the first portion. The second portion of the second spacer SP2 may be provided on the bottom surface of the first spacer SP1. The first and second portions of the second spacer SP2 may be connected to each other to form a stepwise shape. The second portion of the second spacer SP2 may further protrude or extend in a direction parallel to the top surface of the substrate 100, compared with the first portion.

The first spacer SP1 may cover or at least partially overlap a side surface of at least one of the word line contacts WC. The first spacer SP1 may not be provided on a side surface of at least one of the word line contacts WC.

In detail, only the second spacer SP2 may be provided on each of the first, second, and seventh word line contacts WC1, WC2, and WC7. In some embodiments, the first spacer SP1 may be provided on each of the third to sixth word line contacts WC3, WC4, WC5, and WC6.

The first spacers SP1, which are provided on the third to sixth word line contacts WC3, WC4, WC5, and WC6, may be provided to penetrate or extend into the stacked structures of the stack ST with varying numbers of unit layers, thereby resulting in different heights. In the present specification, in the case where the first spacer SP1 is provided to penetrate or extend into n unit-layers, it may be said to have an “n unit height.”

In detail, the first spacer SP1 on the third word line contact WC3 may be provided to penetrate or extend into 2 unit-layers. For example, the first spacer SP1 may be provided to penetrate or extend into the sixth and seventh unit-layers 6F and 7F of the stack ST and may have a 2 unit height.

The first spacer SP1 on the fourth word line contact WC4 may be provided to penetrate or extend into 3 unit-layers. For example, the first spacer SP1 may be provided to penetrate or extend into the fifth unit-layer 5F, the sixth unit-layer 6F, and the seventh unit-layer 7F of the stack ST and may have a 3 unit height.

Each of the first spacers SP1 on the fifth and sixth word line contacts WC5 and WC6 may be provided to penetrate or extend into one unit-layer. For example, each of the first spacers SP1 may be provided to penetrate or extend into the seventh unit-layer 7F of the stack ST and may have a 1 unit height.

The afore-described height difference between the first spacers SP1 may result from a fabrication method, which will be described below in more detail. In addition, the heights of the first spacers SP1 may not be limited to the illustrated examples and may be variously changed.

The contact hole CH may include a recess HP protruding or extending in a direction parallel to the top surface of the substrate 100. A portion of the interlayer insulating layer ILD may be recessed by the recess HP. At least one of the first to seventh contact holes CH1, CH2, CH3, CH4, CH5, CH6, and CH7 may include the recess HP.

In detail, each of the first, second, fifth, and sixth contact holes CH1, CH2, CH5, and CH6 may include one recess HP. Each of the third and fourth contact holes CH3 and CH4 may include two recesses HP disposed in the third direction D3. The number of the recesses HP, which are included in the contact hole CH, may be variously changed.

The spacer SP may cover or at least partially overlap the recess HP. Accordingly, the spacer SP may include a protruding portion PO that protrudes or extends in a direction parallel to the top surface of the substrate 100. The number and position of the protruding portion PO of the spacer SP may vary depending on where they are formed among the first to seventh contact holes.

In detail, the spacer SP, which is provided in each of the first, second, fifth, and sixth contact holes CH1, CH2, CH5, and CH6, may include one protruding portion PO. In addition, the protruding portion PO of the spacer SP, which is provided in each of the first and second contact holes CH1 and CH2, may be provided in the seventh unit-layer 7F of the stack ST. In some embodiments, the protruding portion PO of the spacer SP, which is provided in each of the fifth and sixth contact holes CH5 and CH6, may be provided in the sixth unit-layer 6F of the stack ST. The protruding portion PO of the spacer SP, which is provided in each of the first, second, fifth, and sixth contact holes CH1, CH2, CH5, and CH6, may correspond to the protruding portion PO of the second spacer SP2.

In addition, the spacer SP, which is provided in each of the third and fourth contact holes CH3 and CH4, may include two protruding portions PO arranged in the third direction D3. The protruding portion PO of the spacer SP provided in the third contact hole CH3 may be provided in each of the fifth and seventh unit-layers 5F and 7F of the stack ST. The spacer SP, which includes the protruding portion PO provided in the fifth unit-layer 5F of the stack ST, may correspond to the second spacer SP2. The spacer SP, which includes the protruding portion PO provided in the seventh unit-layer 7F of the stack ST, may correspond to the first spacer SP1. The protruding portion PO of the spacer SP provided in the fourth contact hole CH4 may be provided in each of the fourth and sixth unit-layers 4F and 6F of the stack ST. The spacer SP, which includes the protruding portion PO provided in the fourth unit-layer 4F of the stack ST, may correspond to the second spacer SP2. The spacer SP, which includes the protruding portion PO provided in the sixth unit-layer 6F of the stack ST, may correspond to the first spacer SP1. The protruding portion PO of the second spacer SP2 may be provided on the bottom surface of the first spacer SP1. The protruding portion PO of the second spacer SP2 is inserted into one of the interlayer insulating layers ILD. The protruding portion PO of the first spacer SP1 is inserted into one of the interlayer insulating layers ILD.

The number of the protruding portion PO of the spacer SP may be variously changed, depending on the number of the recesses HP included in the contact hole CH.

Hereinafter, elements included in the first cell array structure CS1 will be described. For convenience in description, the elements included in only the first cell array structure CS1 will be described, but elements included in the second cell array structure CS2 may be configured to have substantially the same features.

The first cell array structure CS1 may include semiconductor patterns SEP, which are spaced apart from each other in the third direction D3, the bit line BL, which is provided on a first edge portion EA1 of each of the semiconductor patterns SEP and extends in the third direction D3, the word lines WL, which are provided to at least partially surround the channel regions CH of the semiconductor patterns SEP and extend in the first direction D1, a data storage pattern DSP, which is provided on a second edge portion EA2 of each of the semiconductor patterns SEP and extends in the third direction D3, capping patterns CP, which are provided between the data storage pattern DSP and the word lines WL, and a gapfill insulating pattern 110 covering or overlapping the bit line BL, a portion of each of the semiconductor patterns SEP, and the word lines WL.

The word line WL may include a gate dielectric layer Gox enclosing or at least partially surrounding the channel region CH of the semiconductor pattern SEP and the gate electrode GE, which is provided on the gate dielectric layer Gox to at least partially surround the channel region CH of the semiconductor pattern SEP. The gate electrode GE may be connected to the gate connection line GL, which is located at substantially the same vertical level.

The data storage pattern DSP may include a storage electrode SE, a plate electrode PE, and a capacitor dielectric layer CIL therebetween. In some embodiments, the three-dimensional semiconductor device may be a dynamic random access memory (DRAM) device, and here, the data storage pattern DSP may be used as a capacitor.

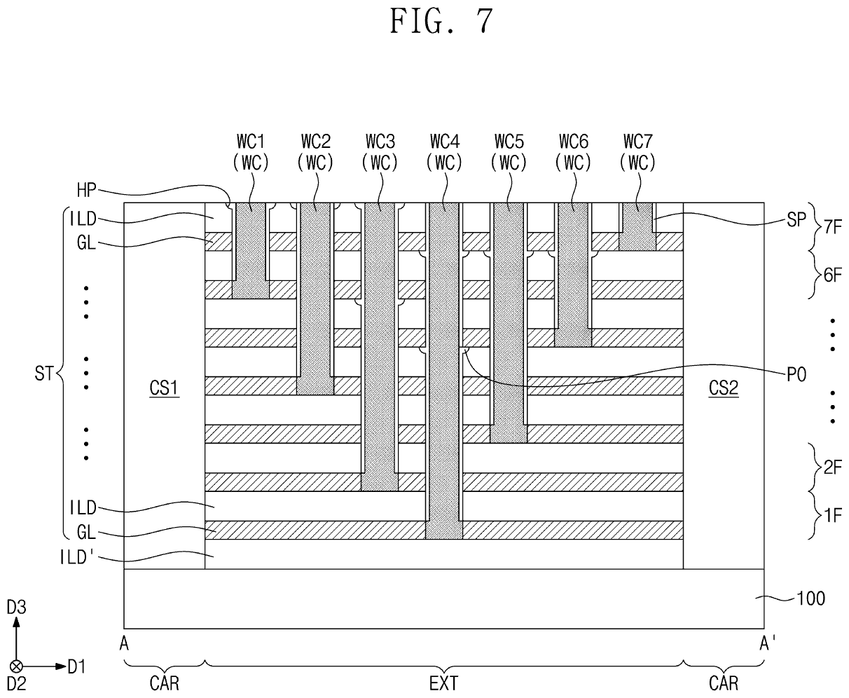

Hereinafter, a three-dimensional semiconductor device according to some embodiments of the present disclosure will be described in more detail with reference to FIGS. 7 to 12. In the following description, a previously-described element may be identified by the same reference number without repeating an overlapping description thereof, for concise description.

FIG. 7 is a sectional view corresponding to the line A-A′ of FIG. 3.

Referring to FIGS. 3 and 7, the first spacer SP1 described with reference to FIGS. 3, 4, and 5 may not be provided in the word line contact WC. In another example, the first spacer SP1 described with reference to FIGS. 3, 4, and 5 may be provided in the word line contact WC, but it may include the same material as the second spacer SP2 described with reference to FIGS. 3, 4, and 5, thereby forming a single or unitary object.

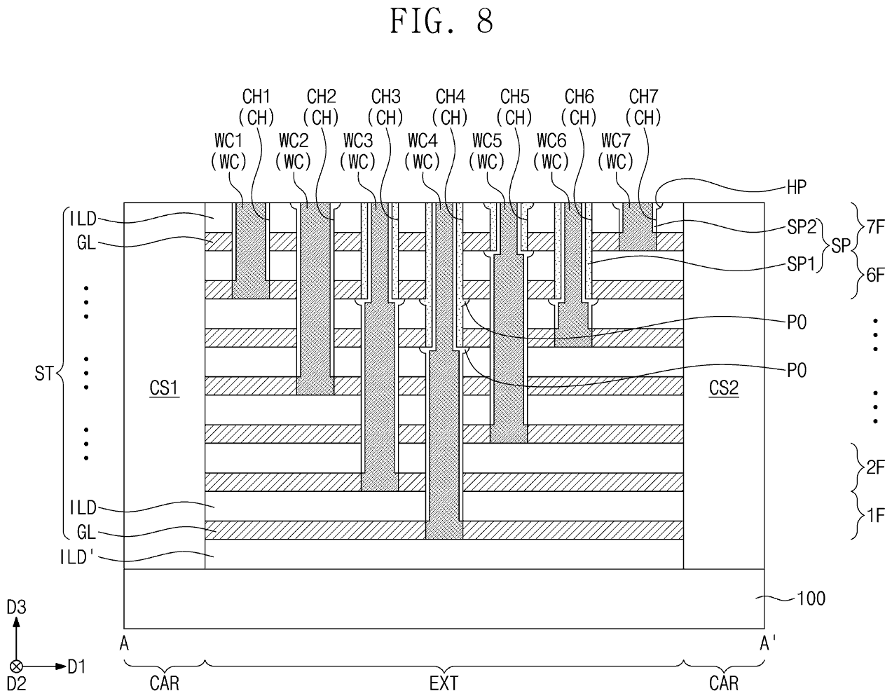

FIG. 8 is a sectional view corresponding to the line A-A′ of FIG. 3.

Referring to FIGS. 3, 4, and 8, the height of the first spacer SP1 and the position of the recess HP in the three-dimensional semiconductor device of FIGS. 3, 4, and 8 may be different from those in the previous embodiments described with reference to FIGS. 3, 4, and 5. This difference may result from a difference between fabrication methods and will be described in more detail with reference to the fabrication method below.

The first spacer SP1 on the sixth word line contact WC6 may be provided to penetrate or extend into 2 unit-layers. For example, the first spacer SP1 may be provided to penetrate or extend into the sixth and seventh unit-layers 6F and 7F of the stack ST and may have a 2 unit height.

Each of the second, third, sixth, and seventh contact holes CH2, CH3, CH6, and CH7 may include one recess HP. Each of the fourth and fifth contact holes CH4 and CH5 may include two recesses HP, which are arranged in the third direction D3.

According to the afore-described number and placement of the recess HP in the contact hole CH, the protruding portion PO of the spacer SP in each of the second and seventh contact holes CH2 and CH7 may be provided in the seventh unit-layer 7F of the stack ST. In addition, the protruding portion PO of the spacer SP in each of the third and sixth contact holes CH3 and CH6 may be provided in the fifth unit-layer 5F of the stack ST. The protruding portion PO of the spacer SP, which is provided in each of the second, third, sixth, and seventh contact holes CH2, CH3, CH6, and CH7, may correspond to the protruding portion PO of the second spacer SP2.

According to the afore-described number and placement of the recess HP in the contact hole CH, the protruding portion PO of the spacer SP provided in the fourth contact hole CH4 may be provided in each of the fourth and fifth unit-layers 4F and 5F of the stack ST. The spacer SP, which includes the protruding portion PO provided in the fourth unit-layer 4F of the stack ST, may correspond to the second spacer SP2. The spacer SP, which includes the protruding portion PO provided in the fifth unit-layer 5F of the stack ST, may correspond to the first spacer SP1. In addition, the protruding portion PO of the spacer SP provided in the fifth contact hole CH5 may be provided in each of the sixth and seventh unit-layers 6F and 7F of the stack ST. The spacer SP, which includes the protruding portion PO provided in the sixth unit-layer 6F of the stack ST, may correspond to the second spacer SP2. The spacer SP, which includes the protruding portion PO provided in the seventh unit-layer 7F of the stack ST, may correspond to the first spacer SP1.

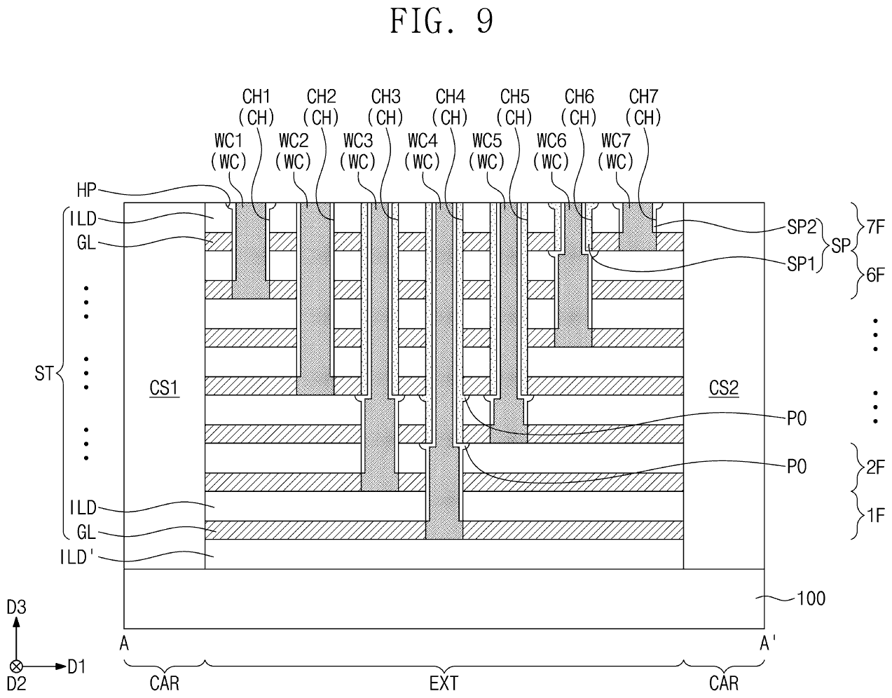

FIG. 9 is a sectional view corresponding to the line A-A′ of FIG. 3.

Referring to FIGS. 3, 4, and 9, the height of the first spacer SP1 and the position of the recess HP in the three-dimensional semiconductor device of FIGS. 3, 4, and 9 may be different from those in the previous embodiments described with reference to FIGS. 3, 4, and 5. This difference may result from the difference in the fabricating method, and this will be described in more detail with reference to the fabrication method to be described below.

The first spacer SP1 on each of the third and fifth word line contacts WC3 and WC5 may be provided to penetrate or extend into 4 unit-layers. For example, the first spacer SP1 may be provided to penetrate or extend into the fourth to seventh unit-layers 4F to 7F of the stack ST and may have a 4 unit height.

The first spacer SP1 on the fourth word line contact WC4 may be provided to penetrate or extend into 5 unit-layers. For example, the first spacer SP1 may be provided to penetrate or extend into the third to seventh unit-layers 3F to 7F of the stack ST and may have a 5 unit height.

Each of the first, third, fifth, and seventh contact holes CH1, CH3, CH5, and CH7 may include one recess HP. Each of the fourth and sixth contact holes CH4 and CH6 may include two recesses HP which are disposed in the third direction D3.

According to the afore-described number and placement of the recess HP in the contact hole CH, the protruding portion PO of the spacer SP in each of the first and seventh contact holes CH1 and CH7 may be provided in the seventh unit-layer 7F of the stack ST. In addition, the protruding portion PO of the spacer SP in each of the third and fifth contact holes CH3 and CH5 may be provided in the third unit-layer 3F of the stack ST. The protruding portion PO of the spacer SP provided in each of the first, third, fifth, and seventh contact holes CH1, CH3, CH5, and CH7 may correspond to the protruding portion PO of the second spacer SP2.

According to the afore-described number and placement of the recess HP in the contact hole CH, the protruding portion PO of the spacer SP provided in the fourth contact hole CH4 may be provided in each of the second and third unit-layers 2F and 3F of the stack ST. The spacer SP, which includes the protruding portion PO provided in the second unit-layer 2F of the stack ST, may correspond to the second spacer SP2. The spacer SP, which includes the protruding portion PO provided in the third unit-layer 3F of the stack ST, may correspond to the first spacer SP1. In addition, the protruding portion PO of the spacer SP provided in the sixth contact hole CH6 may be provided in each of the sixth and seventh unit-layers 6F and 7F of the stack ST. The spacer SP, which includes the protruding portion PO provided in the sixth unit-layer 6F of the stack ST, may correspond to the second spacer SP2. The spacer SP, which includes the protruding portion PO provided in the seventh unit-layer 7F of the stack ST, may correspond to the first spacer SP1.

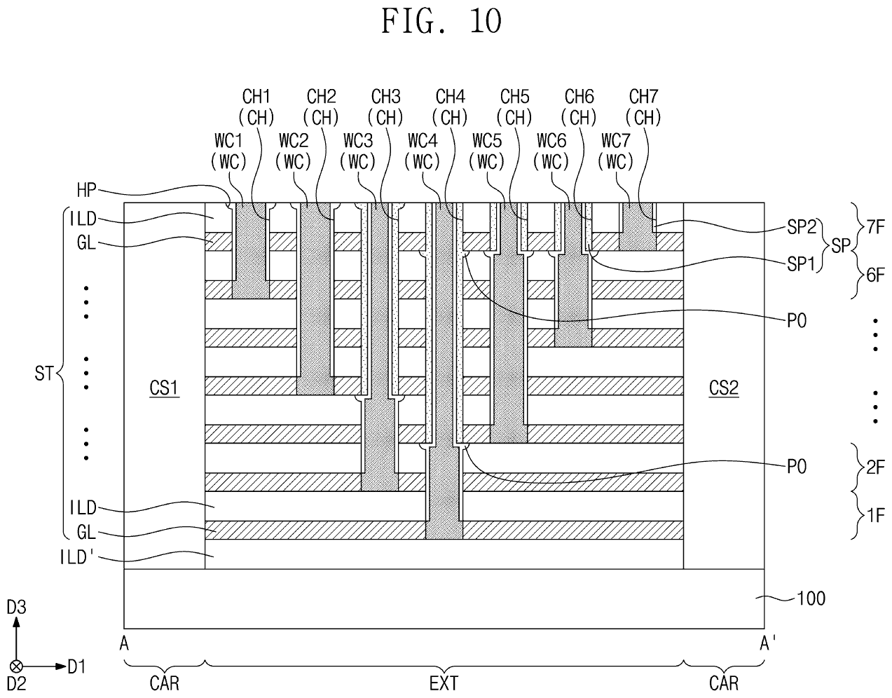

FIG. 10 is a sectional view corresponding to the line A-A′ of FIG. 3.

Referring to FIGS. 3, 4, and 10, the height of the first spacer SP1 and the position of the recess HP in the three-dimensional semiconductor device of FIGS. 3, 4, and 10 may be different from those in the previous embodiments described with reference to FIGS. 3, 4, and 5. This difference may result from a difference between fabrication methods and will be described in more detail with reference to the fabrication method below.

The first spacer SP1 on the third word line contact WC3 may be provided to penetrate or extend into 4 unit-layers. For example, the first spacer SP1 may be provided to penetrate or extend into the fourth to seventh unit-layers 4F to 7F of the stack ST and may have a 4 unit height.

The first spacer SP1 on the fourth word line contact WC4 may be provided to penetrate or extend into 5 unit-layers. For example, the first spacer SP1 may be provided to penetrate or extend into the third to seventh unit-layers 3F to 7F of the stack ST and may have a 5 unit height.

The number and position of the recess HP, which are included in each of the first to seventh contact holes CH1, CH2, CH3, CH4, CH5, CH6, and CH7, may be equal or similar to those in the previous embodiment described with reference to FIG. 5. Hereinafter, features different from the previous embodiment described with reference to FIG. 5 will be described below.

The protruding portion PO of the spacer SP provided in the third contact hole CH3 may be provided in each of the third and seventh unit-layers 3F and 7F of the stack ST. The spacer SP, which includes the protruding portion PO provided in the third unit-layer 3F of the stack ST, may correspond to the second spacer SP2. The spacer SP, which includes the protruding portion PO provided in the seventh unit-layer 7F of the stack ST, may correspond to the first spacer SP1. In addition, the protruding portion PO of the spacer SP provided in the fourth contact hole CH4 may be provided in each of the second and sixth unit-layers 2F and 6F of the stack ST. The spacer SP, which includes the protruding portion PO provided in the second unit-layer 2F of the stack ST, may correspond to the second spacer SP2. The spacer SP, which includes the protruding portion PO provided in the sixth unit-layer 6F of the stack ST, may correspond to the first spacer SP1.

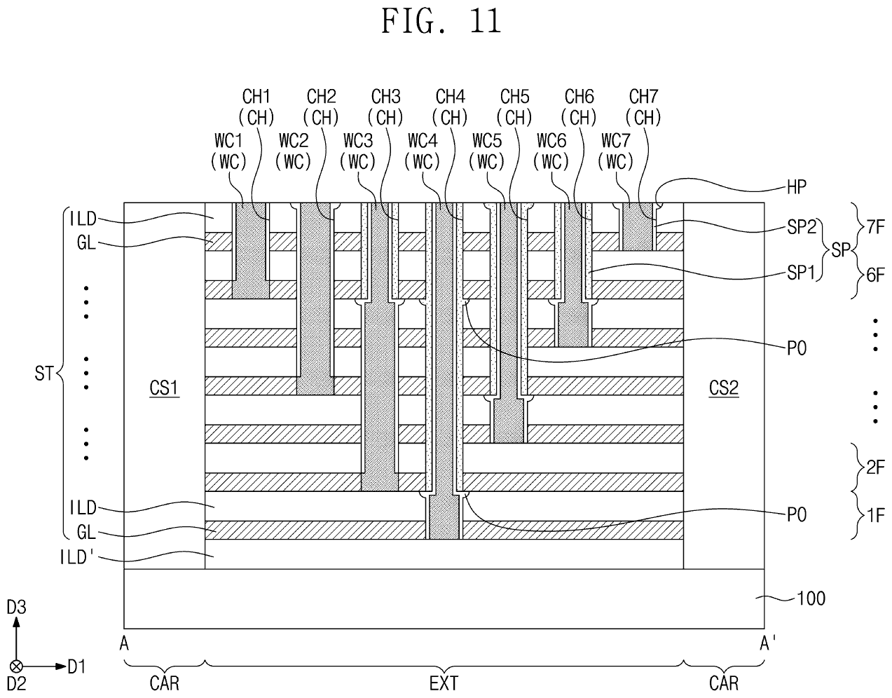

FIG. 11 is a sectional view corresponding to the line A-A′ of FIG. 3.

Referring to FIGS. 3, 4, and 11, the height of the first spacer SP1 and the position of the recess HP in the three-dimensional semiconductor device of FIGS. 3, 4, and 11 may be different from those in the previous embodiments described with reference to FIGS. 3, 4, and 5. This difference may result from a difference between fabrication methods and will be described in more detail with reference to the fabrication method below.

The first spacer SP1 on the fourth word line contact WC4 may be provided to penetrate or extend into 6 unit-layers. For example, the first spacer SP1 may be provided to penetrate or extend into the second to seventh unit-layers 2F to 7F of the stack ST and may have a 6 unit height.

The first spacer SP1 on the fifth word line contact WC5 may be provided to penetrate or extend into 4 unit-layers. For example, the first spacer SP1 may be provided to penetrate or extend into the fourth to seventh unit-layers 4F to 7F of the stack ST and may have a 4 unit height.

The first spacer SP1 on the sixth word line contact WC6 may be provided to penetrate or extend into 2 unit-layers. For example, the first spacer SP1 may be provided to penetrate or extend into the sixth and seventh unit-layers 6F and 7F of the stack ST and may have a 2 unit height.

The number and position of the recess HP, which is included in each of the first to seventh contact holes CH1, CH2, CH3, CH4, CH5, CH6, and CH7, may be equal or similar to those in the previous embodiment described with reference to FIG. 8. Hereinafter, features different from the previous embodiment described with reference to FIG. 8 will be described below.

The protruding portion PO of the spacer SP provided in the fourth contact hole CH4 may be provided to penetrate or extend into the first and fifth unit-layers 1F and 5F of the stack ST. The spacer SP, which includes the protruding portion PO provided in the first unit-layer 1F of the stack ST, may correspond to the second spacer SP2. The spacer SP, which includes the protruding portion PO provided in the fifth unit-layer 5F of the stack ST, may correspond to the first spacer SP1. In addition, the protruding portion PO of the spacer SP provided in the fifth contact hole CH5 may be provided in each of the third and seventh unit-layers 3F and 7F of the stack ST. The spacer SP, which includes the protruding portion PO provided in the third unit-layer 3F of the stack ST, may correspond to the second spacer SP2. The spacer SP, which includes the protruding portion PO provided in the seventh unit-layer 7F of the stack ST, may correspond to the first spacer SP1.

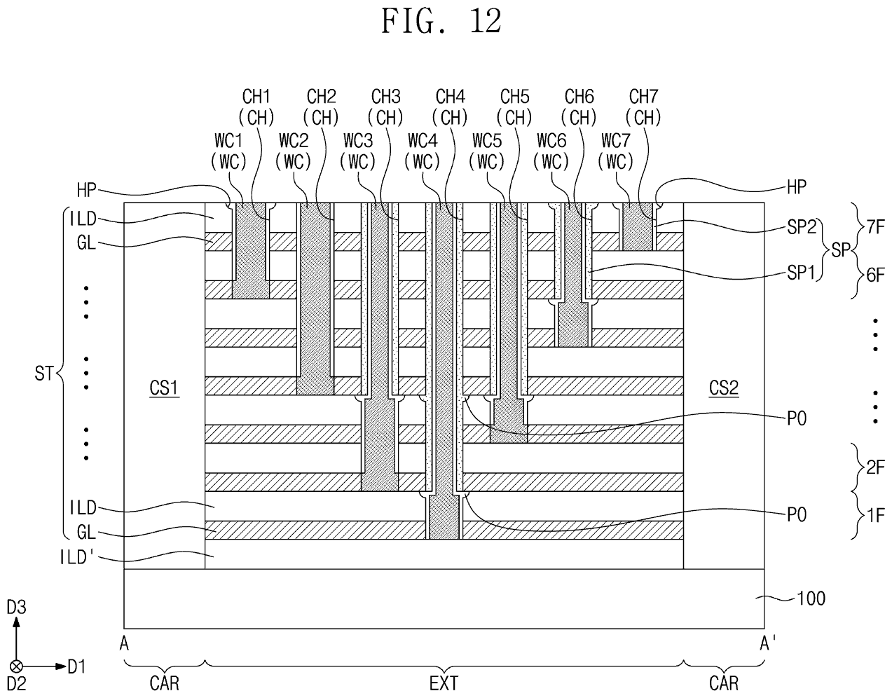

FIG. 12 is a sectional view corresponding to the line A-A′ of FIG. 3.

Referring to FIGS. 3, 4, and 12, the height of the first spacer SP1 and the position of the recess HP in the three-dimensional semiconductor device of FIGS. 3, 4, and 12 may be different from those in the previous embodiments described with reference to FIGS. 3, 4, and 5. This difference may result from a difference between fabrication methods and will be described in more detail with reference to the fabrication method below.

The first spacer SP1 on each of the third and fifth word line contacts WC3 and WC5 may be provided to penetrate or extend into 4 unit-layers. For example, the first spacer SP1 may be provided to penetrate or extend into the fourth to seventh unit-layers 4F to 7F of the stack ST and may have a 4 unit height.

The first spacer SP1 on the fourth word line contact WC4 may be provided to penetrate or extend into 6 unit-layers. For example, the first spacer SP1 may be provided to penetrate or extend into the second to seventh unit-layers 2F to 7F of the stack ST and may have a 6 unit height.

The first spacer SP1 on the sixth word line contact WC6 may be provided to penetrate or extend into 2 unit-layers. For example, the first spacer SP1 may be provided to penetrate or extend into the sixth and seventh unit-layers 6F and 7F of the stack ST and may have a 2 unit height.

The number and position of the recess HP in each of the first to seventh contact holes CH1, CH2, CH3, CH4, CH5, CH6, and CH7 may be equal or similar to those in the previous embodiment described with reference to FIG. 9. Hereinafter, features different from the previous embodiment described with reference to FIG. 9 will be described below.

The protruding portion PO of the spacer SP provided in the fourth contact hole CH4 may be provided in each of the first and third unit-layers 1F and 3F of the stack ST. The spacer SP, which includes the protruding portion PO provided in the first unit-layer 1F of the stack ST, may correspond to the second spacer SP2. The spacer SP, which includes the protruding portion PO provided in the third unit-layer 3F of the stack ST, may correspond to the first spacer SP1. In addition, the protruding portion PO of the spacer SP provided in the sixth contact hole CH6 may be provided in each of the fifth and seventh unit-layers 5F and 7F of the stack ST. The spacer SP, which includes the protruding portion PO provided in the fifth unit-layer 5F of the stack ST, may correspond to the second spacer SP2. The spacer SP, which includes the protruding portion PO provided in the seventh unit-layer 7F of the stack ST, may correspond to the first spacer SP1.

Hereinafter, a three-dimensional semiconductor device according to some embodiments of the present disclosure will be described in more detail with reference to FIGS. 13 to 17. In the following description, a previously-described element may be identified by the same reference number without repeating an overlapping description thereof, for concise description.

FIGS. 13 to 17 are diagrams illustrating a method of fabricating a three-dimensional semiconductor device, according to some embodiments of the present disclosure. In detail, FIGS. 13 to 17 are sectional views corresponding to the line A-A′ of FIG. 3.

Referring to FIGS. 3 and 13, the substrate 100 including the cell regions CAR and the extension region EXT may be prepared. The first and second cell array structures CS1 and CS2 may be formed on the cell regions CAR. A mold structure MS, which includes sacrificial layers SAL and interlayer insulating layers ILD alternately stacked in the third direction D3, may be formed between the first and second cell array structures CS1 and CS2. The mold structure MS may be formed to have a 7 unit-layer stacked structure. That is, the mold structure MS may be a structure in which seven sacrificial layers SAL and seven interlayer insulating layers ILD are alternately stacked. The lowermost interlayer insulating layer ILD' may be formed between the mold structure MS and the substrate 100. The sacrificial layers SAL may include a material having an etch selectivity with respect to the interlayer insulating layers ILD. Accordingly, the interlayer insulating layers ILD may be hardly or less removed when the sacrificial layers SAL are removed in a subsequent process of removing the sacrificial layers SAL. In some embodiments, the sacrificial layer SAL may include a semiconductor material.

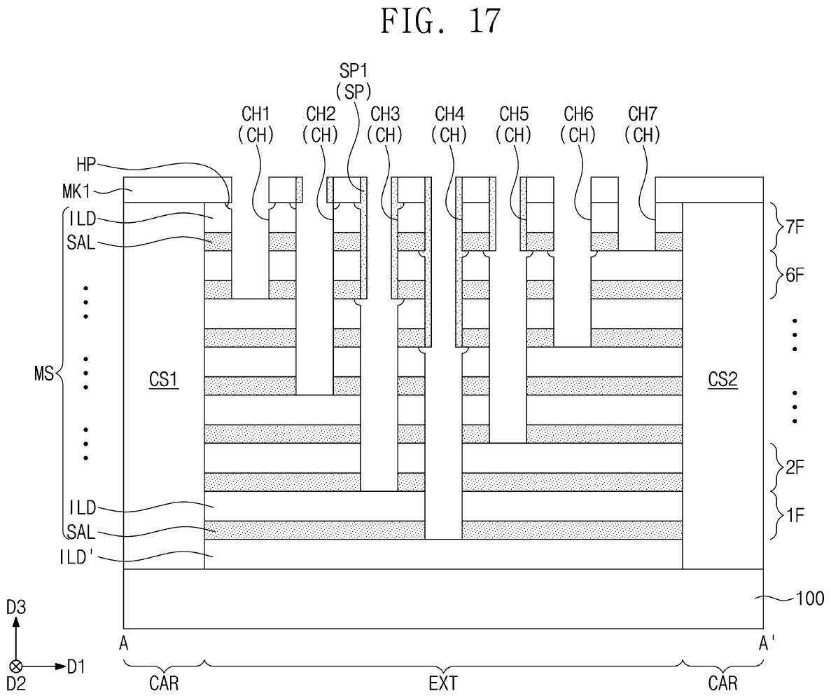

A first mask pattern MK1 and a second mask pattern MK2 may be sequentially provided on the mold structure MS. The first mask pattern MK1 may have a plurality of openings. Some of the openings of the first mask pattern MK1 may be at least partially filled with the second mask pattern MK2, and the others may not be filled with the second mask pattern MK2. Some of the openings of the first mask pattern MK1 may be vertically overlapped with the first to third contact holes CH1, CH2, and CH3, which were described with reference to FIG. 5 or will be described with reference to FIG. 17.

A first patterning process using the first and second mask patterns MK1 and MK2 as a mask may be performed to penetrate or extend into a portion of the mold structure MS. In the present specification, the first patterning process may be defined as a process of removing a portion of the mold structure MS to penetrate or extend into one unit-layer of the mold structure MS. For example, in the case where the first patterning process is performed without any removal process on the mold structure MS, the uppermost one unit-layer (e.g., the seventh unit-layer 7F) of the mold structure MS may be removed by the first patterning process. Accordingly, the fourth to seventh contact holes CH4, CH5, CH6, and CH7 may be formed.

Referring to FIGS. 3 and 14, the second mask pattern MK2 may be removed from a region on the substrate 100. Next, the second mask pattern MK2 may be formed again on the substrate 100. Some of the openings of the first mask pattern MK1 may be at least partially filled with the second mask pattern MK2, and the others may not be filled with the second mask pattern MK2. The openings of the first mask pattern MK1 that are at least partially filled with the second mask pattern MK2 may be vertically overlapped by the second contact hole CH2, which was described with reference to FIG. 5 and will be described with reference to FIG. 17, and may be vertically overlapped with the fifth and seventh contact holes CH5 and CH7.

A first preliminary spacer pattern PSP1 may be formed to conformally cover or overlap the structure on the substrate 100. In detail, the first preliminary spacer pattern PSP1 may be formed to conformally cover or overlap inner surfaces of the openings of the first mask pattern MK1, which are not filled with the second mask pattern MK2, and the fourth and sixth contact holes CH4 and CH6. In some embodiments, the first preliminary spacer pattern PSP1 may include at least one of SiN and SiO₂. In the case where the interlayer insulating layer ILD includes SiO₂, the first preliminary spacer pattern PSP1 may include SiN. In the case where the interlayer insulating layer ILD includes SiN, the first preliminary spacer pattern PSP1 may include SiO₂.

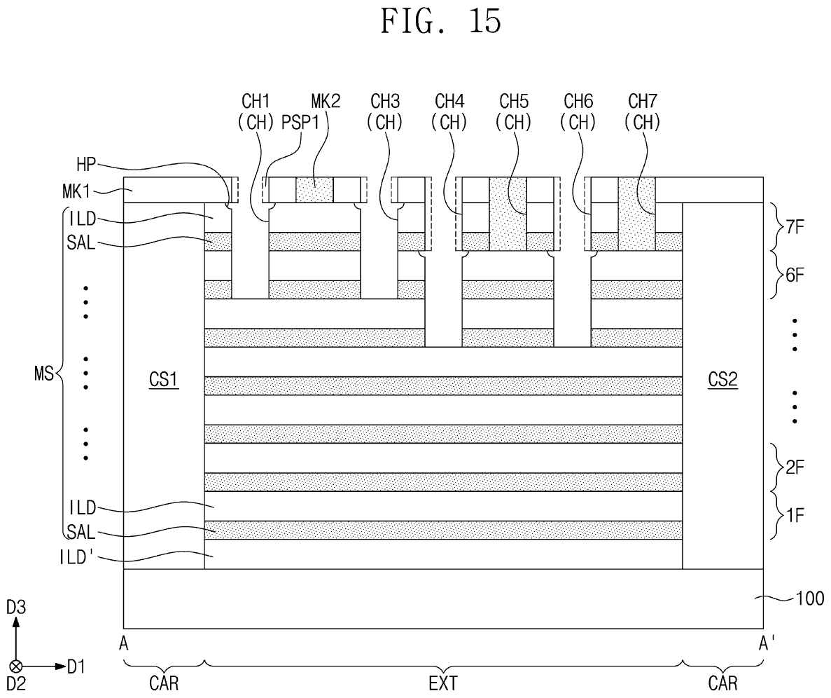

Referring to FIGS. 3 and 15, a removal process may be first performed on a bottom portion of the first preliminary spacer pattern PSP1. The bottom portion of the first preliminary spacer pattern PSP1 may be placed on an inner bottom surface of the opening of the first mask pattern MK1 and on an inner bottom surface of the contact hole CH. A portion of the interlayer insulating layer ILD in contact with the bottom portion of the first preliminary spacer pattern PSP1 may also be removed during the removal process. Accordingly, the recess HP may be formed below the first preliminary spacer pattern PSP1.

A second patterning process using the first and second mask patterns MK1 and MK2 as a mask may be performed to penetrate or extend into a portion of the mold structure MS. In the present specification, the second patterning process may be defined as a process of removing a portion of the mold structure MS to penetrate or extend into 2 unit-layers of the mold structure MS. Accordingly, the first and third contact holes CH1 and CH3 may be formed, and the fourth and sixth contact holes CH4 and CH6 may extend in a downward direction.

During the second patterning process, the first preliminary spacer pattern PSP1 may cover or overlap an inner side surface of the mold structure MS defining each of the fourth and sixth contact holes CH4 and CH6. Accordingly, it may be possible to prevent or inhibit the inner side surface of the mold structure MS from being recessed during the second patterning process.

The first preliminary spacer pattern PSP1 may also be removed during the second patterning process. In this case, the first preliminary spacer pattern PSP1 may be partially removed to have a specific thickness or may be fully removed. In some embodiments, after the second patterning process, a remaining portion of the first preliminary spacer pattern PSP1 may be removed through a cleaning process.

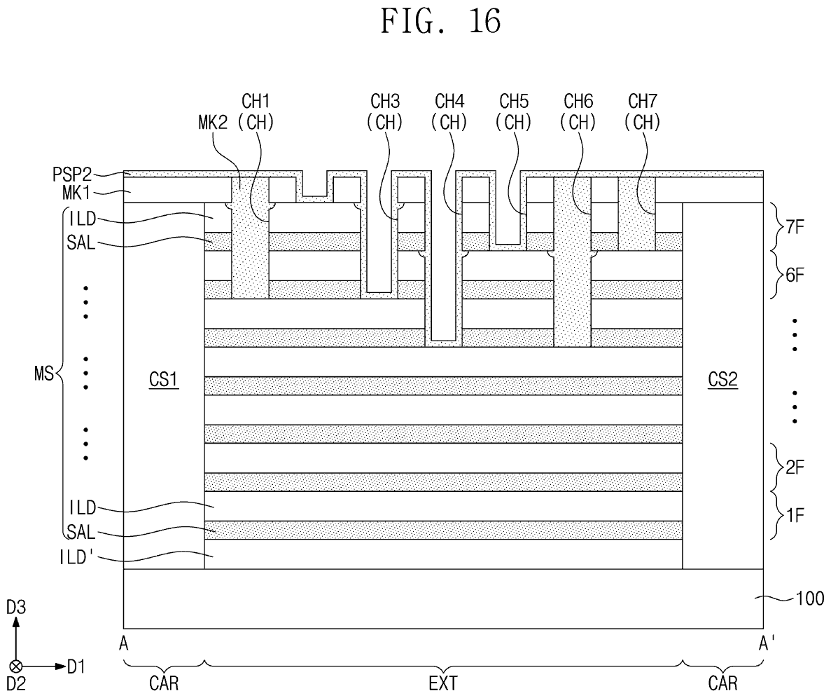

FIG. 16 illustrates an example, in which the first preliminary spacer pattern PSP1 is fully removed, for convenience in description, but the present disclosure is not limited to this example.

Referring to FIGS. 3 and 16, the second mask pattern MK2 may be removed from a region on the substrate 100. Next, the second mask pattern MK2 may be formed again on the substrate 100. Some of the openings of the first mask pattern MK1 may be at least partially filled with the second mask pattern MK2, and the others may not be filled with the second mask pattern MK2. The openings of the first mask pattern MK1 that are at least partially filled with the second mask pattern MK2 may be vertically overlapped by the first and sixth contact holes CH1 and CH6.

A second preliminary spacer pattern PSP2 may be formed to conformally cover or overlap the structure on the substrate 100. In detail, the second preliminary spacer pattern PSP2 may be formed to conformally cover or overlap an inner surface of each of the openings of the first mask pattern MK1, which are not filled with the second mask pattern MK2, and the third to fifth contact holes CH3, CH4, and CH5. In some embodiments, the material for the second preliminary spacer pattern PSP2 may be the same as the material for the first preliminary spacer pattern PSP1.

Referring to FIGS. 3 and 17, a removal process may be first performed on a bottom portion of the second preliminary spacer pattern PSP2. The bottom portion of the second preliminary spacer pattern PSP2 may be placed on an inner bottom surface of the opening of the first mask pattern MK1 and on an inner bottom surface of the contact hole CH. A portion of the interlayer insulating layer ILD in contact with the bottom portion of the second preliminary spacer pattern PSP2 may also be removed during the removal process. Accordingly, the recess HP may be formed below the second preliminary spacer pattern PSP2.

A third patterning process using the first and second mask patterns MK1 and MK2 as a mask may be performed to penetrate or extend into a portion of the mold structure MS. In the present specification, the third patterning process may be defined as a process of removing a portion of the mold structure MS to penetrate 4 unit-layers of the mold structure MS. Accordingly, the second contact hole CH2 may be formed, and the third to fifth contact holes CH3, CH4, and CH5 may extend in a downward direction.

In sum, the second patterning process may be performed to form the first contact hole CH1, and thus, the first contact hole CHI may be formed to penetrate or extend into 2 unit-layers of the mold structure MS. The third patterning process may be performed to form the second contact hole CH2, and thus, the second contact hole CH2 may be formed to penetrate or extend into 4 unit-layers of the mold structure MS. The second and third patterning processes may be sequentially performed to form the third contact hole CH3, and thus, the third contact hole CH3 may be formed to penetrate or extend into 6 unit-layers of the mold structure MS. The first, second, and third patterning processes may be sequentially performed to form the fourth contact hole CH4, and thus, the fourth contact hole CH4 may be formed to penetrate or extend into 7 unit-layers of the mold structure MS. The first and third patterning processes may be sequentially performed to form the fifth contact hole CH5, and thus, the fifth contact hole CH5 may be formed to penetrate or extend into 5 unit-layers of the mold structure MS. The first and second patterning processes may be sequentially performed to form the sixth contact hole CH6, and thus, the sixth contact hole CH6 may be formed to penetrate or extend into 3 unit-layers of the mold structure MS. The first patterning process may be performed to form the seventh contact hole CH7, and thus, the seventh contact hole CH7 may be formed to penetrate or extend into 1 unit-layer of the mold structure MS.

During the third patterning process, the second preliminary spacer pattern PSP2 may cover or at least partially overlap the inner side surface of the mold structure MS defining each of the third to fifth contact holes CH3, CH4, and CH5. Thus, it may be possible to prevent or inhibit the inner side surface of the mold structure MS from being recessed by the third patterning process.

According to some embodiments of the present disclosure, when the contact hole CH is formed to penetrate or extend into a portion of the mold structure MS, the spacer (i.e., the first and second preliminary spacer patterns PSP1 and PSP2) may cover or at least partially overlap the inner side surface of the mold structure MS. Due to the presence of the spacer, it may be possible to prevent or inhibit the inner side surface of the mold structure MS from being unintentionally etched when the removal process is performed to form the contact hole CH and thereby to reduce a bowing phenomenon in the mold structure MS. This may make it possible to reduce a process failure, which occurs when the word line contacts WC are in contact with each other. Thus, the yield of the three-dimensional semiconductor device may be increased.

The second preliminary spacer pattern PSP2 may also be removed during the third patterning process. In this case, the second preliminary spacer pattern PSP2 may be partially removed to have a specific thickness or may be fully removed. After the third patterning process, a remaining portion of the second preliminary spacer pattern PSP2 may be removed through a cleaning process. For convenience in description, the second preliminary spacer pattern PSP2 is illustrated to be left to a specific thickness, but the present disclosure is not limited to this example. A remaining portion of the second preliminary spacer pattern PSP2 may constitute the first spacer SP1 described with reference to FIG. 5.

Referring back to FIGS. 3, 4, and 5, the second spacer SP2 may be formed to conformally cover or overlap an inner space of each of the first to seventh contact holes CH1, CH2, CH3, CH4, CH5, CH6, and CH7. The first to seventh word line contacts WC1, WC2, WC3, WC4, WC5, WC6, and WC7 may be formed to at least partially fill remaining portions of the first to seventh contact holes CH1, CH2, CH3, CH4, CH5, CH6, and CH7, respectively.

In some embodiments, a trench may be additionally formed in the mold structure MS, and then, the trench may be used as a path for a process of replacing the sacrificial layers SAL with the gate connection lines GL. In another embodiment, after the third patterning process described with reference to FIGS. 3 and 17, the first to seventh contact holes CH1, CH2, CH3, CH4, CH5, CH6, and CH7 may be used as the path for the replacement process. The stack ST may be formed as a result of the afore-described fabrication process.

In the case where the first, second, and third patterning processes are sequentially performed during the fabrication process, the three-dimensional semiconductor device may be fabricated to have the structure described with reference to FIGS. 3, 4, and 5.

TABLE 1

| | 1 | 2 | 3 | 4 | 5 | 6 | 7 |
|---|---|---|---|---|---|---|---|
| First patterning process | X | X | X | ◯ | ◯ | ◯ | ◯ |
| Second patterning process | ◯ | X | ◯ | ◯ | X | ◯ | X |
| Third patterning process | X | ◯ | ◯ | ◯ | ◯ | X | X |
| Height of First spacer | — | — | 2 | 3 | 1 | 1 | — |
| (Number of Unit layers) | | | | | | | |

Table 1 summarizes the selective application of the first, second, and third patterning processes to the first to seventh contact holes CH1, CH2, CH3, CH4, CH5, CH6, and CH7 during the fabrication of the three-dimensional semiconductor device described with reference to FIGS. 3, 4, and 5, as well as the resulting heights of the first spacers SP1. In Table 1, the numbers 1 to 7 indicate the first to seventh contact holes CH1, CH2, CH3, CH4, CH5, CH6, and CH7, respectively.

The order of the first, second, and third patterning processes may be changed from that in the examples described with reference to FIGS. 13 to 17. Accordingly, the heights of the first and second preliminary spacer patterns PSP1 and PSP2, which are respectively described with reference to FIGS. 14 and 16, may be changed depending on the order of the first, second, and third patterning processes.

In the case where the second, first, and third patterning processes are sequentially performed during the fabrication process, the three-dimensional semiconductor device may be fabricated to have the structure described with reference to FIGS. 3, 4, and 8.

TABLE 2

| | 1 | 2 | 3 | 4 | 5 | 6 | 7 |
|---|---|---|---|---|---|---|---|
| Second patterning process | ◯ | X | ◯ | ◯ | X | ◯ | X |
| First patterning process | X | X | X | ◯ | ◯ | ◯ | ◯ |
| Third patterning process | X | ◯ | ◯ | ◯ | ◯ | X | X |
| Height of First spacer | — | — | 2 | 3 | 1 | 2 | — |
| (Number of Unit layers) | | | | | | | |

Table 2 summarizes the selective application of the second, first, and third patterning processes to the first to seventh contact holes CH1, CH2, CH3, CH4, CH5, CH6, and CH7 during the fabrication of the three-dimensional semiconductor device described with reference to FIGS. 3, 4, and 8, as well as the resulting heights of the first spacers SP1.

In the case where the third, first, and second patterning processes are sequentially performed during the fabrication process, the three-dimensional semiconductor device may be fabricated to have the structure described with reference to FIGS. 3, 4, and 9.

TABLE 3

| | 1 | 2 | 3 | 4 | 5 | 6 | 7 |
|---|---|---|---|---|---|---|---|
| Third patterning process | X | ◯ | ◯ | ◯ | ◯ | X | X |
| First patterning process | X | X | X | ◯ | ◯ | ◯ | ◯ |
| Second patterning process | ◯ | X | ◯ | ◯ | X | ◯ | X |
| Height of First spacer | — | — | 4 | 5 | 4 | 1 | — |
| (Number of Unit layers) | | | | | | | |

Table 3 summarizes the selective application of the third, first, and second patterning processes to the first to seventh contact holes CH1, CH2, CH3, CH4, CH5, CH6, and CH7 during the fabrication of the three-dimensional semiconductor device described with reference to FIGS. 3, 4, and 9, as well as the resulting heights of the first spacers SP1.

In the case where the first, third, and second patterning processes are sequentially performed during the fabrication process, the three-dimensional semiconductor device may be fabricated to have the structure described with reference to FIGS. 3, 4, and 10.

TABLE 4

| | 1 | 2 | 3 | 4 | 5 | 6 | 7 |
|---|---|---|---|---|---|---|---|
| First patterning process | X | X | X | ◯ | ◯ | ◯ | ◯ |
| Third patterning process | X | ◯ | ◯ | ◯ | ◯ | X | X |
| Second patterning process | ◯ | X | ◯ | ◯ | X | ◯ | X |
| Height of First spacer | — | — | 4 | 5 | 1 | 1 | — |
| (Number of Unit layers) | | | | | | | |

Table 4 summarizes the selective application of the first, third, and second patterning processes to the first to seventh contact holes CH1, CH2, CH3, CH4, CH5, CH6, and CH7 during the fabrication of the three-dimensional semiconductor device described with reference to FIGS. 3, 4, and 10, as well as the resulting heights of the first spacers SP1.

In the case where the second, third, and first patterning processes are sequentially performed during the fabrication process, the three-dimensional semiconductor device may be fabricated to have the structure described with reference to FIGS. 3, 4, and 11.

TABLE 5

| | 1 | 2 | 3 | 4 | 5 | 6 | 7 |
|---|---|---|---|---|---|---|---|
| Second patterning process | ◯ | X | ◯ | ◯ | X | ◯ | X |
| Third patterning process | X | ◯ | ◯ | ◯ | ◯ | X | X |
| First patterning process | X | X | X | ◯ | ◯ | ◯ | ◯ |
| Height of First spacer | — | — | 2 | 6 | 4 | 2 | — |
| (Number of Unit layers) | | | | | | | |

Table 5 summarizes the selective application of the second, third, and first patterning processes to the first to seventh contact holes CH1, CH2, CH3, CH4, CH5, CH6, and CH7 during the fabrication of the three-dimensional semiconductor device described with reference to FIGS. 3, 4, and 11, as well as the resulting heights of the first spacers SP1.

In the case where the third, second, and first patterning processes are sequentially performed during the fabrication process, the three-dimensional semiconductor device may be fabricated to have the structure described with reference to FIGS. 3, 4, and 12.

TABLE 6

| | 1 | 2 | 3 | 4 | 5 | 6 | 7 |
|---|---|---|---|---|---|---|---|
| Third patterning process | X | ◯ | ◯ | ◯ | ◯ | X | X |
| Second patterning process | ◯ | X | ◯ | ◯ | X | ◯ | X |
| First patterning process | X | X | X | ◯ | ◯ | ◯ | ◯ |
| Height of First spacer | — | — | 4 | 6 | 4 | 2 | — |
| (Number of Unit layers) | | | | | | | |

Table 6 summarizes the selective application of the third, second, and first patterning processes to the first to seventh contact holes CH1, CH2, CH3, CH4, CH5, CH6, and CH7 during the fabrication of the three-dimensional semiconductor device described with reference to FIGS. 3, 4, and 12, as well as the resulting heights of the first spacers SP1.

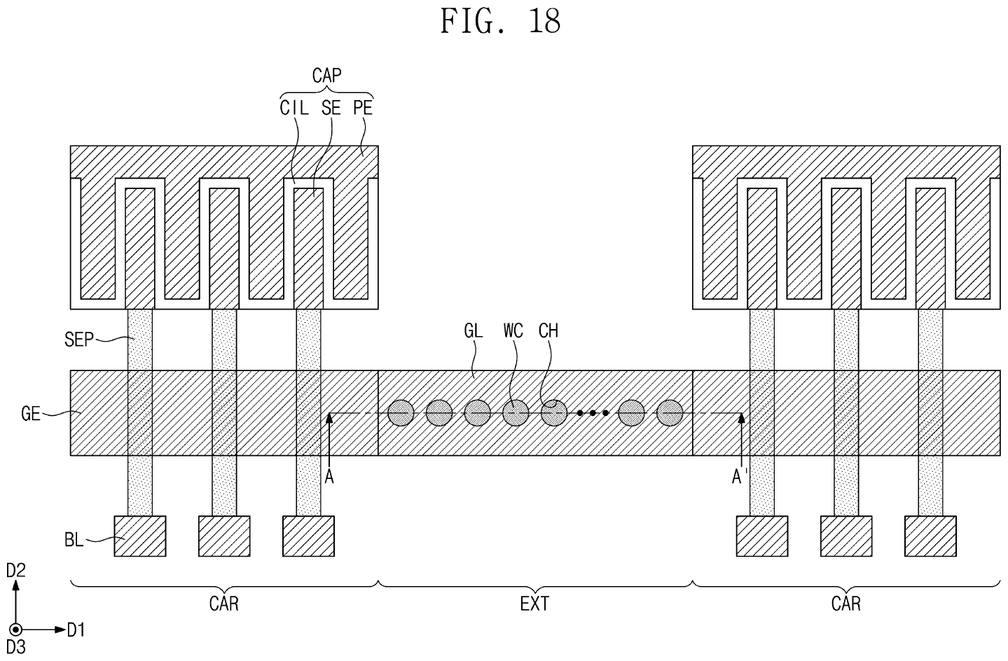

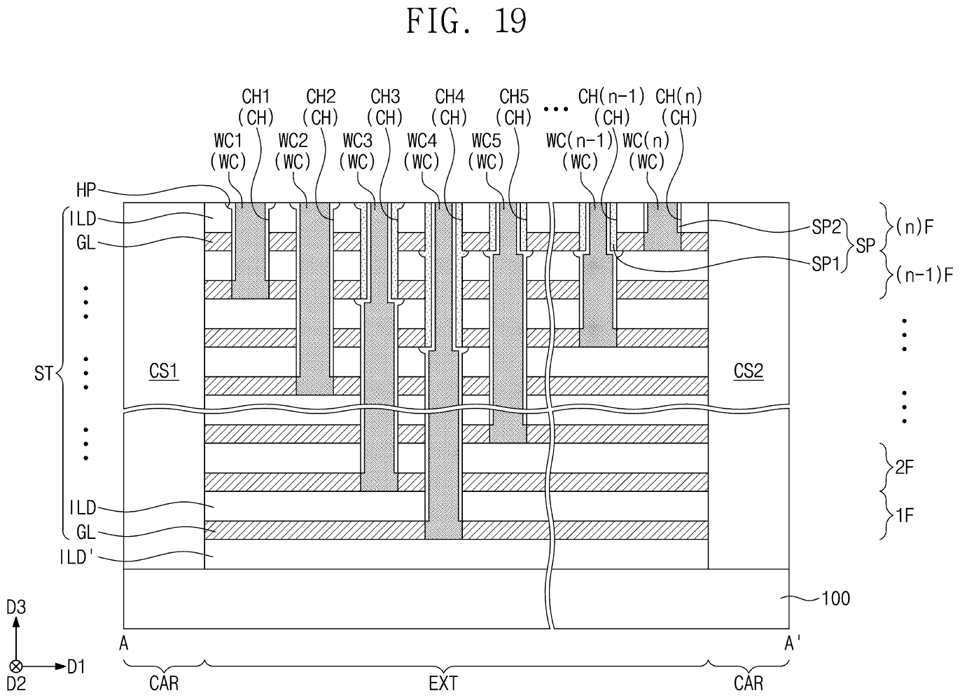

FIG. 18 is a plan view illustrating a three-dimensional semiconductor device according to some embodiments of the present disclosure. FIG. 19 is a sectional view corresponding to a line A-A′ of FIG. 18.

Although the stack ST is illustrated as the 7 unit-layer stacked structure in FIGS. 3, 4, and 5, the present disclosure is not limited to this example. For example, the stack ST may be provided to have an n unit-layer stacked structure, as shown in FIGS. 18 and 19. The stack ST may be provided to include n gate connection lines GL and n interlayer insulating layers ILD, which are alternately stacked in the third direction D3. In addition, the word line contact WC may be provided to include n word line contacts WC (i.e., the first to n-th word line contacts WC1 to WC(n)). Table 7 summarizes the number of the protruding portions PO in the spacer SP and the height of the first spacer SP1 according to the number of the unit-layers. The height of the first spacer SP1 in Table 7 is the sum of the heights of the first spacers SP1 formed in the word line contacts WC. Furthermore, in the method of fabricating the three-dimensional semiconductor device described with reference to FIGS. 18 and 19, the first to n-th patterning process may be sequentially performed in the order from the first patterning process to the n-th patterning process.

TABLE 7

| | (2¹-1) | (2²-1) | (2³-1) | (2⁴-1) | |
|---|---|---|---|---|---|
| Number of | unit- | unit- | unit- | unit- | (2ⁿ-1) |
| Unit layers | layers | layers | layers | layers | unit-layers |
| Number of Protruding portions | 0 | 2 | 8 | 24 | (n-1)2⁽ⁿ⁻¹⁾ |
| Height of First spacer (Number of Unit layers) | 0 | 1 | 7 | 35 | $\frac{( {4}^{n} - 1 )}{6} - {2}^{n - 1} + \frac{1}{2}$ |

According to some embodiments of the present disclosure, a spacer may cover or at least partially overlap an inner side surface of a mold structure when a contact hole is formed to penetrate or extend into a portion of the mold structure. Thus, due to the presence of the spacer, it may be possible to prevent or inhibit the inner side surface of the mold structure from being unintentionally etched in a removal process to form the contact hole and thereby to reduce a bowing phenomenon in the mold structure. This may make it possible to reduce a process failure, which is caused by an unnecessary contact between word line contacts to be formed in a subsequent step. Thus, the yield of the three-dimensional semiconductor device may be increased.

While example embodiments of the present disclosure have been particularly shown and described, it will be understood by one of ordinary skill in the art that variations in form and detail may be made therein without departing from the spirit and scope of the attached claims.

What is claimed is:

1. A three-dimensional semiconductor device, comprising:
a substrate comprising a cell region and an extension region;
a stack on the extension region, the stack comprising a plurality of gate connection lines and a plurality of interlayer insulating layers alternately stacked on the substrate;
a first word line contact that extends into at least one gate connection line of the plurality of gate connection lines and is connected to a first gate connection line of the at least one gate connection line;
a first spacer between the first word line contact and the stack; and
a second spacer between the first spacer and the first word line contact, wherein a first portion of the second spacer is spaced apart from the at least one first gate connection line by the first spacer,
wherein a second portion of the second spacer is in contact with the at least one first gate connection line, and
wherein the first portion of the second spacer is on the second portion of the second spacer.

2. The three-dimensional semiconductor device of claim 1, wherein a distance between the second portion of the second spacer and a top surface of the substrate in a direction that is perpendicular to the top surface of the substrate is less than a distance between a bottom surface of the first spacer and the top surface of the substrate in the direction.

3. The three-dimensional semiconductor device of claim 1, wherein a height of the second spacer in a direction that is perpendicular to a top surface of the substrate is larger than a height of the first spacer in the direction.

4. The three-dimensional semiconductor device of claim 1, wherein the second spacer comprises a protruding portion, wherein a bottom surface of the first spacer is on the protruding portion, and wherein the protruding portion extends in a direction that is parallel to a top surface of the substrate.

5. The three-dimensional semiconductor device of claim 4, wherein the protruding portion of the second spacer is in one of the interlayer insulating layers.

6. The three-dimensional semiconductor device of claim 1, wherein the first spacer comprises a protruding portion that extends in a that is direction parallel to a top surface of the substrate, and wherein the protruding portion of the first spacer is in one of the interlayer insulating layers.

7. The three-dimensional semiconductor device of claim 1, wherein each of the second portion of the second spacer and the first spacer comprises a protruding portion that extends in a that is direction parallel to a top surface of the substrate.

8. The three-dimensional semiconductor device of claim 1, wherein the first portion of the second spacer and the second portion of the second spacer are in contact with each other and have a stepwise shape.

9. The three-dimensional semiconductor device of claim 1, further comprising:
a second word line contact connected to a second gate connection line of the plurality of gate connection lines,
wherein a height of the first word line contact in a first direction that is perpendicular to a top surface of the substrate is larger than a height of the second word line contact in the first direction, and
wherein a height in the first direction of the first spacer is larger than a height in the first direction of the first spacer.

10. The three-dimensional semiconductor device of claim 1, further comprising:
a second word line contact connected to a second gate connection line of the plurality of gate connection lines,
wherein a height of the first word line contact in a first direction that is perpendicular to a top surface of the substrate is larger than a height of the second word line contact in the first direction, and
wherein a height in the first direction of a first portion of the first spacer is substantially equal to a height in the first direction of the first spacer.

11. The three-dimensional semiconductor device of claim 1, further comprising a first cell array structure and a second cell array structure that are on the cell region and are spaced apart from each other with the stack therebetween,
wherein each of the first cell array structure and the second cell array structure comprises:
a plurality of semiconductor patterns spaced apart from each other in a first that is direction perpendicular to a top surface of the substrate;
word lines that at least partially surround the semiconductor patterns and extend in a second direction that is parallel to the top surface of the substrate;
a bit line that is connected to a first end portion of each of the semiconductor patterns and extends in the first direction; and
a data storage pattern that is connected to a second end portion of each of the semiconductor patterns and extends in the first direction.

12. The three-dimensional semiconductor device of claim 11, wherein each of the plurality of gate connection lines is connected to a corresponding one of the word lines of the first cell array structure and a corresponding one of the word lines of the second cell array structure.

13. The three-dimensional semiconductor device of claim 1, wherein the stack has a substantially constant height in a direction that is perpendicular to a top surface of the substrate.

14. A three-dimensional semiconductor device, comprising:
a substrate comprising a cell region and an extension region;
a stack on the extension region, the stack comprising a plurality of gate connection lines and a plurality of interlayer insulating layers that are alternately stacked on the substrate;
a word line contact that extends into at least one gate connection line of the plurality of gate connection lines and is connected to a first gate connection line of the at least one gate connection line; and
a spacer between the word line contact and the stack,
wherein the spacer comprises protruding portions that extend in a first direction that is parallel to a top surface of the substrate, and
wherein the protruding portions are spaced apart from each other in a second that is direction perpendicular to the top surface of the substrate.

15. The three-dimensional semiconductor device of claim 14, wherein each of the protruding portions is in a corresponding one of the interlayer insulating layers.

16. The three-dimensional semiconductor device of claim 14, wherein the spacer comprises a first spacer between the word line contact and the stack and a second spacer between the first spacer and the word line contact.

17. The three-dimensional semiconductor device of claim 16, wherein a first protruding portion of the protruding portions is part of the first spacer,
wherein a second protruding portion of the protruding portions is part of the second spacer, and
wherein a distance between the first protruding portion and a top surface of the substrate in the second direction is greater than a distance between the second protruding portion and the top surface of the substrate in the second direction.

18. The three-dimensional semiconductor device of claim 16, wherein a first portion of the second spacer is spaced apart from the at least one gate connection line by the first spacer and is on a second portion of the second spacer that is in contact with the at least one gate connection line.

19. The three-dimensional semiconductor device of claim 16, wherein a height of the second spacer in the second direction is larger than a height of the first spacer in the second direction.

20. A three-dimensional semiconductor device, comprising:
a substrate comprising a cell region and an extension region;
a first cell array structure and a second cell array structure that are on the cell region and are spaced apart from each other in a first direction that is parallel to a top surface of the substrate;
a stack that is on the extension region and between the first cell array structure and the second cell array structure, the stack comprising a plurality of gate connection lines and a plurality of interlayer insulating layers that are alternately stacked on the substrate;
a word line contact that extends into at least one gate connection line of the plurality of gate connection lines and is connected to a first gate connection line of the plurality of gate connection lines;
a first spacer between the word line contact and the stack; and
a second spacer between the first spacer and the word line contact,
wherein each of the first cell array structure and the second cell array structure comprises:
a plurality of semiconductor patterns that are spaced apart from each other in a second direction that is perpendicular to the top surface of the substrate;
word lines that at least partially surround the semiconductor patterns and extend in the first direction;
a bit line that is connected to a first end portion of each of the plurality of semiconductor patterns and extends in the second direction; and
a data storage pattern that is connected to a second end portion of each of the plurality of semiconductor patterns and extends in the second direction,
wherein a first portion of the second spacer is spaced apart from the at least one gate connection line by the first spacer,
wherein a second portion of the second spacer is in contact with the at least one gate connection line, and
wherein the first portion of the second spacer is on the second portion of the second spacer.
